(19) United States
(12) Patent Application Publication
(10) Pub. No.: US 2019/0357389 A1
(43) Pub. Date: Nov. 21, 2019

(54) TRANSMISSION DEVICE

(71) Applicant: FUJITSU LIMITED, Kawasaki-shi (JP)

(72) Inventor: Osamu SAITO, Kawasaki (JP)

(73) Assignee: FUJITSU LIMITED, Kawasaki-shi (JP)

(21) Appl. No.: 16/404,919

(22) Filed: May 7, 2019

(30) Foreign Application Priority Data
May 15, 2018 (JP) 2018-093956

(51) Int. Cl. H05K 7/20

(52) U.S. Cl. CPC H05K 7/20727; H05K 7/20172; H05K 7/20145; H05K 7/20309; H05K 7/20809; H05K 7/20154

(57) ABSTRACT

A transmission device includes a separator that separates a space inside a housing so as to form a space where a first heat-generating component is disposed and a space where a second heat-generating component is disposed, a first heat sink provided for the first heat-generating component, a second heat sink that is provided for the second heat-generating component and that has a larger width than a width of the first heat sink, and a dividing member that divides the cooling air having flowed into the space inside the housing so as to guide the cooling air of a first flow amount to the space where the first heat-generating component is disposed and the cooling air of a second flow amount which is larger than the first flow amount to the space where the second heat-generating component is disposed.

### CROSS-REFERENCE TO RELATED APPLICATION

This application is based upon and claims the benefit of priority of the prior Japanese Patent Application No. 2018-93956, filed on May 15, 2018, the entire contents of which are incorporated herein by reference.

### FIELD

The embodiments discussed herein are related to transmission device.

### BACKGROUND

In related-art transmission devices such as blade-type server devices, a plurality of electronic components that generate heat during operation are disposed in a space inside a housing. Heat generated by the electronic components may cause malfunction of the electronic components. Accordingly, in such transmission devices, the electronic components that are heat generating elements are cooled by causing cooling air to flow into the space inside the housing. Furthermore, in such transmission devices, heat sinks that facilitate heat dissipation using the cooling air are provided for the electronic components.

Related art is disclosed in, for example, International Publication Pamphlet No. WO 2010/064299 and Japanese Laid-open Patent Publication Nos. 2013-74219 and 2016-157237.

Meanwhile, in the transmission devices, as the capacity of the electronic components increases, heat generated by the electronic components tends to increase. As the heat generated by the electronic components increases, the size of the heat sinks provided for the electronic components increases. In particular, when the size of heat sinks provided for electronic components that generate relatively large amount of heat (referred to as “high heat-generating components” hereinafter) increases, these heat sinks may interfere with other electronic components disposed around the high heat-generating components. Thus, there is a limit of the increase in size of the heat sinks provided for the high heat-generating components. Accordingly, it is expected to efficiently cool, using the cooling air, the electronic components that are heat generating elements.

In view of the above description, it is desirable that cooling efficiency using the cooling air be able to be improved in the transmission devices.

### SUMMARY

According to an aspect of the embodiments, a transmission device includes a housing, a separator that vertically separates a space inside the housing so as to form a space where a first heat-generating component is disposed and a space where a second heat-generating component which generates a larger amount of heat than an amount of heat generated by the first heat-generating component is disposed, a first heat sink provided for the first heat-generating component, a second heat sink that is provided for the second heat-generating component and that has, in a direction perpendicular to a direction in which cooling air flows into the space inside the housing, a larger width than a width of the first heat sink, and a dividing member that divides the cooling air having flowed into the space inside the housing so as to guide the cooling air of a first flow amount to the space where the first heat-generating component is disposed and the cooling air of a second flow amount which is larger than the first flow amount to the space where the second heat-generating component is disposed.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view of the appearance of a transmission device according to a first embodiment;

FIG. 2 is a perspective view of an inner structure of the transmission device according to the first embodiment;

FIG. 3 is a side sectional view of the inner structure of the transmission device according to the first embodiment;

FIG. 4 is a perspective view of a dividing member;

FIG. 5 are simulation results representing examples of the relationship between the width of a second heat sink and the temperature of an electronic component;

FIG. 6 illustrates an example of the width of the second heat sink;

FIG. 7 illustrates an example of the width of the second heat sink;

FIG. 8 is a simulation result representing an example of a temperature distribution of electronic components measured in an evaluation example;

FIG. 9 is a simulation result representing an example of a temperature distribution of electronic components measured in a comparative example;

FIG. 10 is a side sectional view of an inner structure of the transmission device according to a second embodiment; and

FIG. 11 is a perspective view of a deflector.

### DESCRIPTION OF EMBODIMENTS

Embodiments of a transmission device disclosed in the present application will be described in detail below with reference to the drawings. It is to be understood that techniques to be disclosed are not limited to these embodiments.

### First Embodiment

[Structure of a Transmission Device]

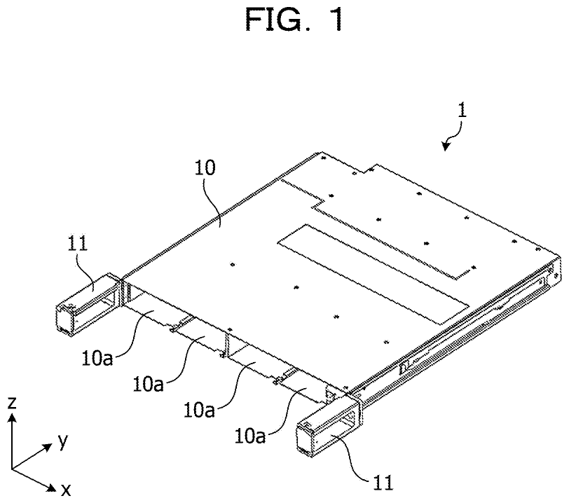

FIG. 1 is a perspective view of the appearance of a transmission device 1 according to a first embodiment. The transmission device 1 illustrated in FIG. 1 is, for example, a server device or the like of a blade type removably mountable in a rack (not illustrated). The transmission device 1 includes a housing 10. The housing 10 is a box including a bottom plate, a top plate facing the bottom plate, a pair of side walls facing each other, a front surface, and a rear surface. In the following description, it is assumed that the bottom plate and the top plate of the housing 10 are parallel to the xy plane, the pair of the side walls of the housing 10 are parallel to the yz plane, and the front surface and the rear surface of the housing 10 are parallel to the xz plane. Furthermore, the x direction is referred to as a width direction of the housing 10, the y direction is referred to as a depth direction of the housing 10, and the z direction is referred to as a height direction of the housing 10. Furthermore, a direction indicated by an arrow of the z axis is referred to as an upper direction, and the opposite direction to the direction indicated by the arrow of the z axis is referred to as the lower direction. Furthermore, a direction indicated by an arrow of the y axis is referred to as a rear side, and the opposite direction to the direction indicated by the arrow of the y axis is referred to as a front side. Furthermore, a surface of the housing 10 on the front side is referred to as the front surface of the housing 10, and a surface of the housing 10 on the rear side is referred to as the rear surface of the housing 10.

As illustrated in FIG. 1, a plurality of slots 10a are formed in the front surface of the housing 10. Plug-in units (PIUs) 20, which will be described later, are to be inserted into the slots 10a. In the example illustrated in FIG. 1, four slots 10a are formed. Also, securing members 11 are provided in the front surface of the housing 10. The securing members 11 are used to secure the transmission device 1 to a rack (not illustrated).

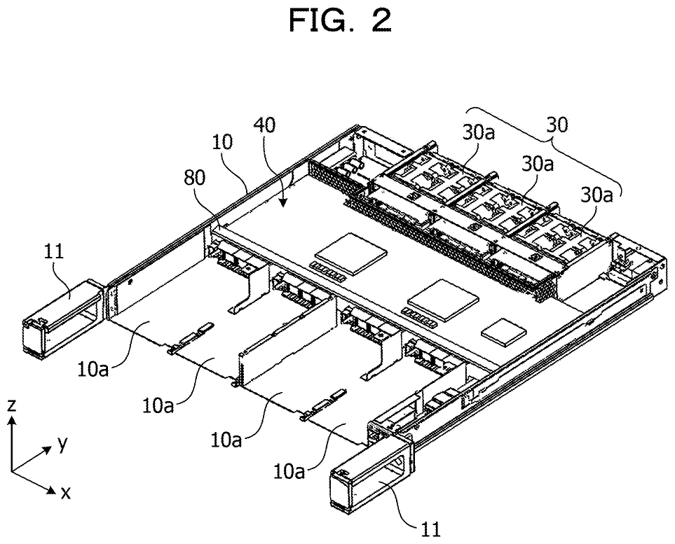

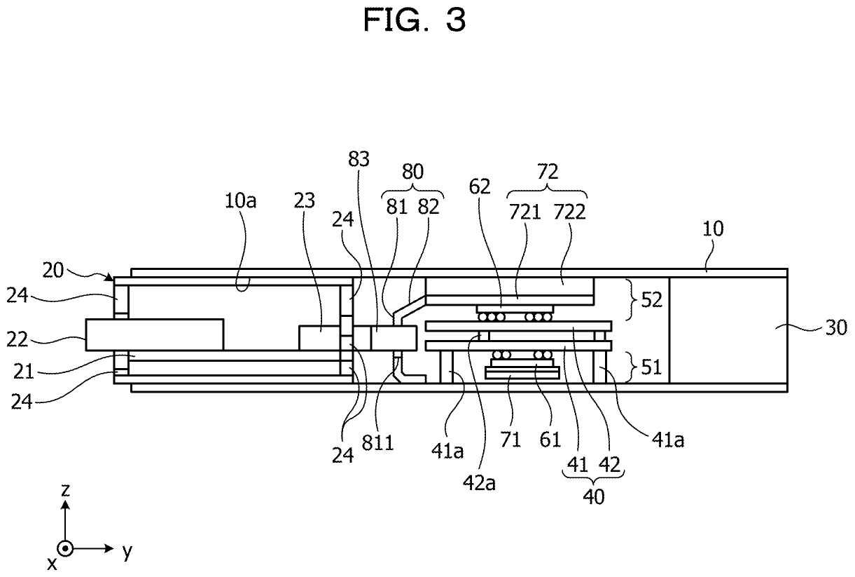

FIG. 2 is a perspective view of an inner structure of the transmission device 1 according to the first embodiment. FIG. 3 is a side sectional view of the inner structure of the transmission device 1 according to the first embodiment. The top plate of the housing 10 is omitted from FIG. 2. Some components such as PIUs 20 are also omitted from FIG. 2.

As illustrated in FIGS. 2 and 3, the PIUs 20 are inserted into the front surface side of the housing 10 (that is, the slots 10a), and a fan unit 30 is provided on the rear surface side of the housing 10. Each of the PIUs 20 includes, in a housing thereof, a board 21, an optical module 22, and a connector 23. The optical module 22 is provided on the board 21 and transmits and receives optical signals. The connector 23 is provided on the board 21 and allows the PIU 20 and the transmission device 1 to be electrically connected to each other therethrough. A plurality of airholes 24 are formed in the front surface and the rear surface of the housing of the PIU 20.

The fan unit 30 includes a single fan 30a or a plurality of fans 30a. In the example illustrated in FIG. 2, three fans 30a are illustrated. The fan unit 30 generates cooling air passing through the airholes 24 of the PIUs 20 in a direction from the front surface of the housing 10 toward the rear surface of the housing 10.

A space is formed between the PIUs 20 and the fan unit 30. Hereinafter, this space formed between the PIUs 20 and the fan unit 30 is, where appropriate, referred to as a “space inside the housing 10”. The cooling air having passed through the airholes 24 of the PIUs 20 flows into the space inside the housing 10. At least part of the space inside the housing 10 is separated into a lower space 51 and an upper space 52 by a separator 40. The separator 40 includes a board 41 and a board 42. The board 41 is supported above the bottom plate of the housing 10 by support columns 41a. The board 42 is supported above the board 41 by support columns 42a. The board 41 and the board 42 are electrically connected to each other through, for example, a connector.

An electronic component 61 is disposed in the lower space 51, and an electronic component 62 is disposed in the upper space 52. A plurality of electronic components 61 may be disposed in the lower space 51, and a plurality of electronic components 62 may be disposed in the upper space 52. The electronic component 61 is secured by soldering to a lower surface of the board 41 of the separator 40, and the electronic component 62 is secured by soldering to an upper surface of the board 42 of the separator 40. The electronic component 61 and the electronic component 62 generate heat when operated. The amount of heat generated by the electronic component 62 is larger than the amount of heat generated by the electronic component 61. The electronic component 61 corresponds to an example of a “first heat-generating component”, and the electronic component 62 corresponds to an example of a “second heat-generating component”.

When seen in the height direction of the housing 10, the electronic component 61 and the electronic component 62 are disposed in a central region of the housing 10. The central region of the housing 10 refers to a region occupied by a trapezoid an upper base of which is a line segment along the front surface of the housing 10 and a lower base of which is a line segment along a front surface of the fan unit 30.

The electronic component 61 is provided with a first heat sink 71 that facilitates heat dissipation from the electronic component 61. The electronic component 62 is provided with a second heat sink 72 that facilitates heat dissipation from the electronic component 62. The second heat sink 72 includes a base plate 721 secured to the electronic component 62 and a fin 722 that stands erect on a surface of the base plate 721 on the opposite side to the electronic component 62. The base plate 721 and the fin 722 are formed of the same material, for example, aluminum or the like. The base plate 721 may be formed of a material having a higher thermal conductivity than that of the material of the fin 722, for example, copper or the like. Alternatively, the base plate 721 may be a vapor chamber that conducts heat by utilizing evaporation of liquid in a chamber.

Furthermore, in a direction perpendicular to the direction in which the cooling air flows into the space inside the housing 10 (that is, the width direction of the housing 10), the width of the second heat sink 72 is larger than that of the first heat sink 71. Here, since the electronic component 62 generates a larger amount of heat than that generated by the electronic component 61, the size of the second heat sink 72 provided for the electronic component 62 tends to increase. For example, the width of the second heat sink 72 tends to increase. In the case where another electronic component such as an electronic component 61 is disposed around the electronic component 62, the second heat sink 72 may interfere with the other electronic component when the size of the second heat sink 72 increases. In this regard, according to the present embodiment, the electronic component 61 is disposed in the lower space 51 and the electronic component 62 is disposed in the upper space 52. Thus, the other electronic component such as an electronic component 61 is not disposed around the electronic component 62. Accordingly, in the direction perpendicular to the direction in which the cooling air flows into the space inside the housing 10 (that is, the width direction of the housing 10), even when the width of the second heat sink 72 is larger than that of the first heat sink 71, the interference of the second heat sink 72 with the other electronic component is avoided.

A dividing member 80 is provided between the PIUs 20 and the separator 40. The dividing member 80 divides the cooling air having passed through the airholes 24 of the PIUs 20 and having flowed into the space inside the housing 10. That is, the dividing member 80 divides the cooling air having flowed into the space inside the housing 10 so as to guide the cooling air of a flow amount of Q1 to the lower space 51 where the electronic component 61 is disposed and the cooling air of a flow amount of Q2 larger than the flow amount of Q1 to the upper space 52 where the electronic component 62 is disposed. This allows the dividing member 80 to concentrate the cooling air to the second heat sink 72 provided for the electronic component 62 generating relatively large amount of heat. Accordingly, the second heat sink 72 may efficiently dissipate heat from the electronic component 62. As a result, cooling efficiency using the cooling air may be improved in the transmission device 1.

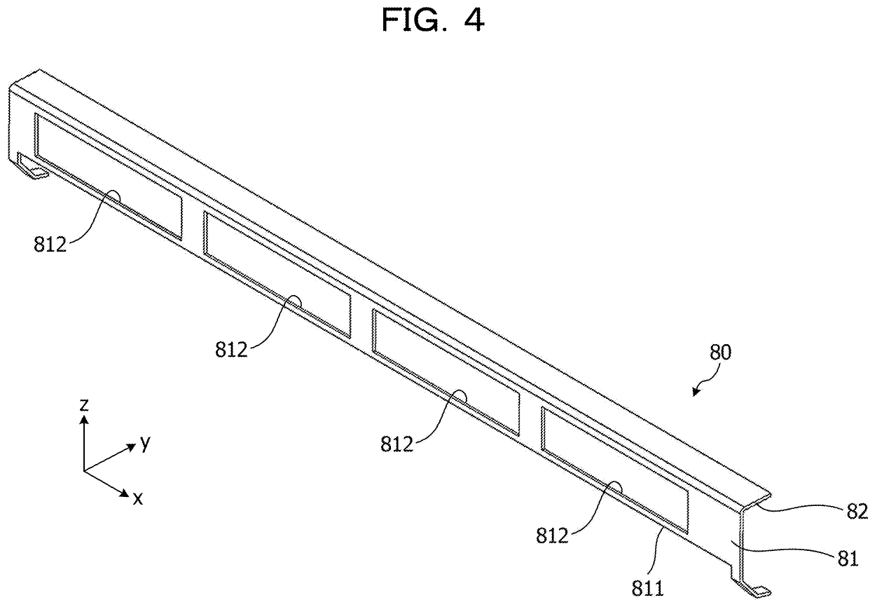

FIG. 4 is a perspective view of the dividing member 80. As illustrated in FIGS. 3 and 4, the dividing member 80 includes a main body portion 81 and an extension portion 82.

The main body portion 81 stands erect from the bottom plate of the housing 10 in such a length that the main body portion 81 does not reach the top plate of the housing 10. The main body portion 81 has a substantially U shape. That is, the main body portion 81 includes two leg portions secured to the bottom plate of the housing 10. A cut 811 is formed between the two leg portions. The cut 811 allows the cooling air of the flow amount of Q1 to pass therethrough to the lower space 51 where the electronic component 61 is disposed. This cooling air of the flow amount of Q1 is obtained by dividing the cooling air having flowed into the space inside the housing 10. Furthermore, securing holes 812 are formed in a central portion of the main body portion 81. Connectors 83 through which the PIUs 20 and the transmission device 1 are electrically connected to one another are secured to the securing holes 812. The connectors 83 are connected to the board 42 of the separator 40 through cables (not illustrated). When the connectors 23 of the PIUs 20 and the connectors 83 are connected to one another, the PIUs 20 are electrically connected to circuitry printed on the board 42.

The extension portion 82 extends from the main body portion 81 toward the fin 722 of the second heat sink 72. For example, the extension portion 82 extends from the main body portion 81 toward the fin 722 of the second heat sink 72 so as to be in contact with the base plate 721 of the second heat sink 72. The extension portion 82 guides the cooling air of the flow amount of Q2 (>Q1) to the fin 722. This cooling air of the flow amount of Q2 is obtained by dividing the cooling air having flowed into the space inside the housing 10. This allows the dividing member 80 to concentrate the cooling air to the fin 722 that increases an area for thermal conduction of the second heat sink 72. Accordingly, the second heat sink 72 may efficiently dissipate heat from the electronic component 62. As a result, the cooling efficiency using the cooling air may be further improved in the transmission device 1.

[Relationship Between the Width of the Second Heat Sink 72 and the Temperature of the Electronic Component 62]

Meanwhile, it is preferable that, in the transmission device 1, the width of the second heat sink 72 in the direction perpendicular to the direction in which the cooling air flows into the space inside the housing 10 (that is, the width direction of the housing 10) be as large as possible from the viewpoint of increasing the thermal conduction area of the second heat sink 72. Thus, it is preferable that the width of the second heat sink 72 be larger than the width of the fan unit 30. Furthermore, it is more preferable that the width of the second heat sink 72 be equal to the width between the pair of the side walls of the housing 10 facing each other with the space inside the housing 10 interposed therebetween. Furthermore, when a plurality of the electronic components 62 are disposed in the upper space 52, it is preferable that the sum of the widths of the second heat sinks 72 provided for the respective electronic components 62 be equal to the width between the pair of the side walls of the housing 10 facing each other with the space inside the housing 10 interposed therebetween.

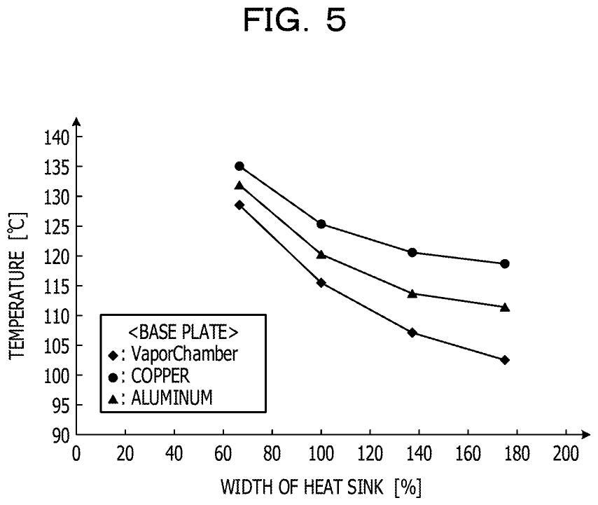

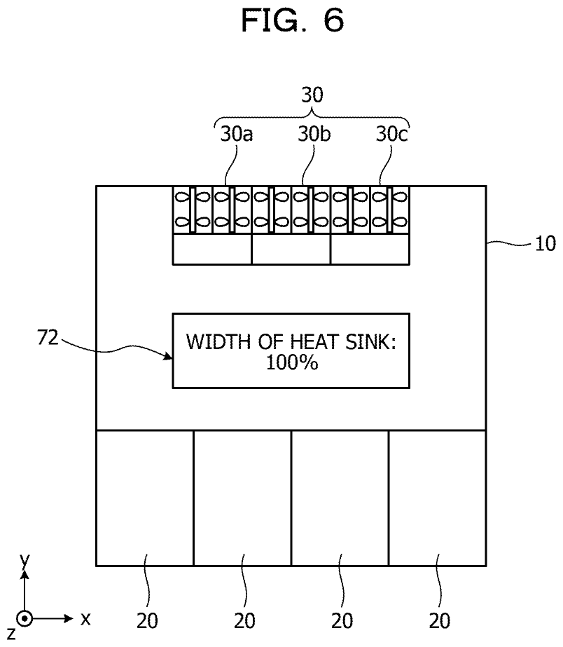

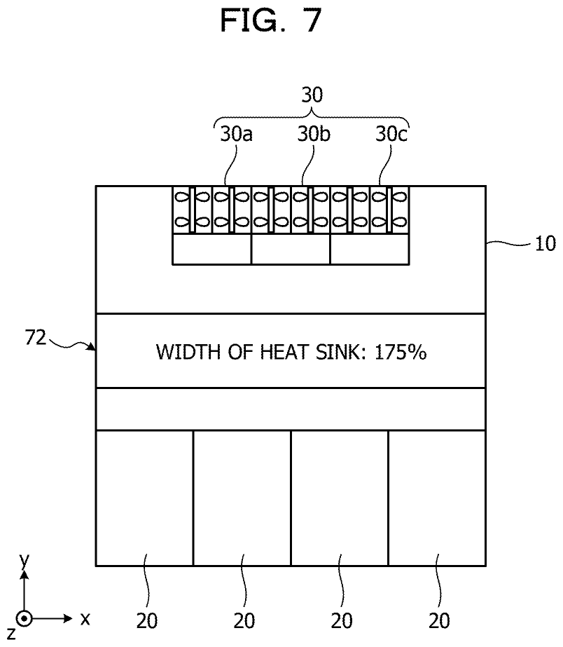

FIG. 5 illustrates simulation results representing examples of the relationship between the width of the second heat sink 72 and the temperature of the electronic component 62. In FIG. 5, the horizontal axis represents the width (%) of the second heat sink 72 in the direction perpendicular to the direction in which the cooling air flows into the space inside the housing 10 (that is, the width direction of the housing 10), and the vertical axis represents the temperature (° C.) of the electronic component 62. In FIG. 5, variations in temperature of the electronic component 62 corresponding to the width of the second heat sink 72 are represented for the types of the base plate 721 of the second heat sink 72. The width of the second heat sink 72 is represented by the ratio thereof to the width of the fan unit 30. FIGS. 6 and 7 illustrate examples of the width of the second heat sink 72. When the width of the second heat sink 72 is 100%, the width of the second heat sink 72 is equal to the width of the fan unit 30 as illustrated in FIG. 6. Furthermore, when the width of the second heat sink 72 is 175%, the width of the second heat sink 72 is, as illustrated in FIG. 7, equal to the width between the pair of the side walls of the housing 10 facing each other with the space inside the housing 10 interposed therebetween.

As illustrated in FIG. 5, as the width of the second heat sink 72 increases, the temperature of the electronic component 62 reduces independently of the types of the base plate 721 of the second heat sink 72. For example, when the width of the second heat sink 72 is larger than 100%, that is, the width of the second heat sink 72 is larger than the width of the fan unit 30, the temperature of the electronic component 62 becomes lower than a predetermined allowable temperature (for example, 125° C.). Furthermore, when the width of the second heat sink 72 is 175%, that is, the width of the second heat sink 72 is equal to the width between the pair of the side walls of the housing 10 facing each other with the space inside the housing 10 interposed therebetween, the temperature of the electronic component 62 becomes the lowest.

[Evaluation Simulations]

Next, evaluation simulations performed for evaluating the cooling efficiency using the cooling air are described. In an evaluation example, the temperature of the electronic component 62 when the cooling air is applied to the transmission device 1 according to the present embodiment is simulated. In the transmission device 1, as described above, the space inside the housing 10 is separated into the lower space 51 and the upper space 52 by the separator 40, and the dividing member 80 divides the cooling air so as to guide the cooling air of the flow amount of Q1 to the lower space 51 and the cooling air of the flow amount of Q2 (>Q1) to the upper space 52. Furthermore, in the transmission device 1, two electronic components 62 are disposed in the upper space 52, and the sum of the widths of the second heat sinks 72 provided for the respective electronic components 62 is equal to the width between the pair of the side walls of the housing 10 facing each other with the space inside the housing 10 interposed therebetween.

In contrast, in a comparative example, the temperature of the electronic component 62 when the cooling air is applied to another transmission device is simulated. In the other transmission device, the space inside the housing 10 is a single space and the cooling air is not divided. Furthermore, in the other transmission device, two electronic components 62 are disposed in the space of the housing 10, and the sum of the widths of heat sinks provided for the respective electronic components 62 is sufficiently smaller than the width between the pair of the side walls of the housing 10 facing each other with the space inside the housing 10 interposed therebetween.

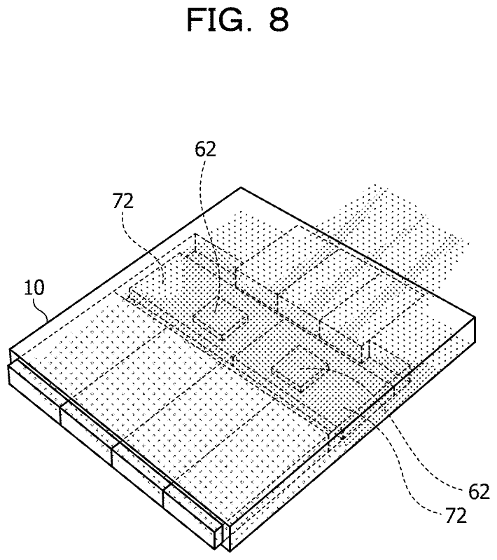

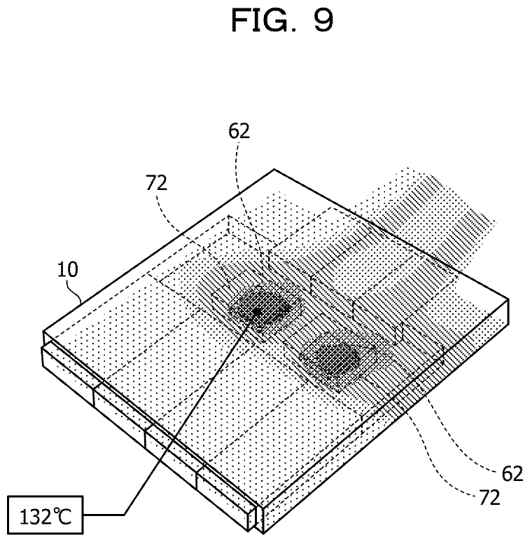

FIG. 8 is a simulation result representing an example of a temperature distribution of the electronic components 62 measured in the evaluation example. FIG. 9 is a simulation result representing an example of a temperature distribution of the electronic components 62 measured in the comparative example. As illustrated in FIGS. 8 and 9, compared to the temperature of the electronic components 62 of the other transmission device in which the space inside the housing 10 is a single space, the temperature of the electronic components 62 of the transmission device 1 in which the space inside the housing 10 is separated into the lower space 51 and the upper space 52 is reduced by about 30 degrees. That is, it has been confirmed that the cooling efficiency using the cooling air may be improved when the space inside the housing 10 is vertically separated and the cooling air is divided so as to guide the cooling air of a relatively large flow amount to the upper space 52 where the electronic component 62 that generates a relatively large amount of heat is disposed.

As has been described, the transmission device 1 according to the present embodiment includes the housing 10, the separator 40, the first heat sink 71, the second heat sink 72, and the dividing member 80. The separator 40 vertically separates the space inside the housing 10 so as to form the lower space 51 and the upper space 52. The electronic component 61 is disposed in the lower space 51, and the electronic component 62 that generates a larger amount of heat than that generated by the electronic component 61 is disposed in the upper space 52. The first heat sink 71 is provided for the electronic component 61. The second heat sink 72 is provided for the electronic component 62. In the direction perpendicular to the direction in which the cooling air flows into the space inside the housing 10, the width of the second heat sink 72 is larger than that of the first heat sink 71. The dividing member 80 divides the cooling air having flowed into the space inside the housing 10 so as to guide the cooling air of the flow amount of Q1 to the lower space 51 where the electronic component 61 is disposed and the cooling air of the flow amount of Q2 larger than the flow amount of Q1 to the space where the electronic component 62 is disposed.

With this structure of the transmission device 1, the dividing member 80 is able to concentrate the cooling air to the second heat sink 72 provided for the electronic component 62 generating relatively large amount of heat. Accordingly, the second heat sink 72 may efficiently dissipate heat from the electronic component 62. As a result, the cooling efficiency using the cooling air may be improved. Furthermore, without another electronic component disposed around the electronic component 62, the width of the second heat sink 72 is able to increase so as to increase the thermal conduction area of the second heat sink 72. Thus, the cooling efficiency using the cooling air may be further improved.

### Second Embodiment

The difference between the transmission device 1 according to the first embodiment and the transmission device 1 according to a second embodiment is that the transmission device 1 according to the second embodiment includes a deflector that deflects the cooling air having passed through the airholes 24 of the PIUs 20 and having flowed into the space inside the housing 10.

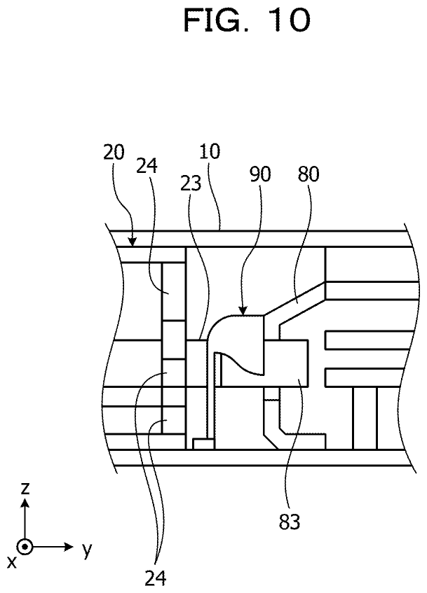

FIG. 10 is a side sectional view of an inner structure of the transmission device 1 according to the second embodiment.

As illustrated in FIG. 10, the deflector 90 is removably mounted to the PIUs 20. The deflector 90 deflects the cooling air having passed through the airholes 24 of the PIUs 20 and having flowed into the space inside the housing 10.

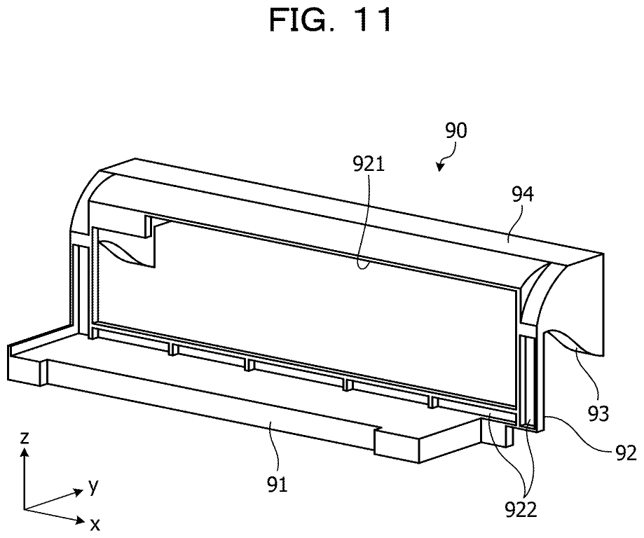

FIG. 11 is a perspective view of the deflector 90. The deflector 90 includes a base portion 91, a main body portion 92, a first extension portion 93, and a second extension portion 94. The base portion 91 is in contact with the bottom plate of the housing 10. The main body portion 92 stands erect from the base portion 91 in the height direction of the housing 10. A fitting hole 921 is formed in a central portion of the main body portion 92. The connectors 23 of the PIUs 20 are fitted into the fitting hole 921. Furthermore, openings 922 are formed in a region of the main body portion 92 surrounding the fitting hole 921. The openings 922 allow the cooling air having passed through the airholes 24 of the PIUs 20 to pass therethrough to the space inside the housing 10.

The first extension portion 93 extends from the main body portion 92 toward the cut 811 of the dividing member 80. The first extension portion 93 deflects the cooling air that have passed through the airholes 24 of the PIUs 20 and the openings 922, having flowed into the space inside the housing 10, and is directed toward the cut 811 of the dividing member 80.

The second extension portion 94 extends from the main body portion 92 toward the extension portion 82 of the dividing member 80. The second extension portion 94 deflects the cooling air that have passed through the airholes 24 of the PIUs 20, having flowed into the space inside the housing 10, and is directed toward the extension portion 82 of the dividing member 80.

As described above, the transmission device 1 according to the present embodiment includes the deflector 90. The deflector 90 is removably mounted to the PIUs 20 and deflects the cooling air having passed through the airholes 24 of the PIUs 20 and having flowed into the space inside the housing 10.

With the structure of this transmission device 1, the cooling air having flowed into the space inside the housing 10 is deflected. Thus, the cooling efficiency using the cooling air may be further improved.

The first extension portion 93 may be movable relative to the main body portion 92. With the first extension portion 93 movable relative to the main body portion 92, the flow amount of the cooling air directed toward the cut 811 of the dividing member 80 and the flow amount of the cooling air directed toward the extension portion 82 of the dividing member 80 are adjusted where appropriate. Thus, the dividing member 80 may efficiently concentrate the cooling air to the second heat sink 72 provided for the electronic component 62 generating relatively large amount of heat.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A transmission device comprising:
a housing;
a separator that vertically separates a space inside the housing so as to form a space where a first heat-generating component is disposed and a space where a second heat-generating component which generates a larger amount of heat than an amount of heat generated by the first heat-generating component is disposed;
a first heat sink provided for the first heat-generating component;
a second heat sink that is provided for the second heat-generating component and that has, in a direction perpendicular to a direction in which cooling air flows into the space inside the housing, a larger width than a width of the first heat sink; and
a dividing member that divides the cooling air having flowed into the space inside the housing so as to guide the cooling air of a first flow amount to the space where the first heat-generating component is disposed and the cooling air of a second flow amount which is larger than the first flow amount to the space where the second heat-generating component is disposed.

2. The transmission device according to claim 1, further comprising:
a plug-in unit that has an airhole and that is inserted into a front surface side of the housing; and
a fan unit that is provided on a rear surface side of the housing and that generates the cooling air passing through the airhole of the plug-in unit;
wherein
the space inside the housing is formed between the plug-in unit and the fan unit, and
the dividing member divides the cooling air having passed through the airhole of the plug-in unit and having flowed into the space inside the housing.

3. The transmission device according to claim 2, wherein
in the direction perpendicular to the direction in which the cooling air flows into the space inside the housing, the width of the second heat sink is larger than a width of the fan unit.

4. The transmission device according to claim 2, wherein
in the direction perpendicular to the direction in which the cooling air flows into the space inside the housing, the width of the second heat sink is equal to a width between a pair of side walls of the housing facing each other with the space inside the housing interposed therebetween.

5. The transmission device according to claim 1, wherein
the second heat sink includes
a base plate secured to the second heat-generating component, and
a fin that stands erect from a surface of the base plate on an opposite side to the second heat-generating component, and
the dividing member includes
a main body portion that stands erect from a bottom plate of the housing in such a length that the main body portion does not reach a top plate of the housing and that has a cut which allows the cooling air of the first flow amount to pass therethrough to the space where the first heat-generating component is disposed, and
an extension portion that extends from the main body portion toward the fin so as to guide the cooling air of the second flow amount to the fin.

6. The transmission device according to claim 5, wherein
the base plate is formed of a material having a higher thermal conductivity than a thermal conductivity of a material of the fin.

7. The transmission device according to claim 5, wherein
the base plate is a vapor chamber that conducts heat by utilizing evaporation of liquid in a chamber.

8. The transmission device according to claim 5, further comprising:
a deflector that is removably mounted to a plug-in unit and that deflects the cooling air having passed through an airhole of the plug-in unit and having flowed into the space inside the housing.
